(19) United States
(12) Patent Application Publication
(10) Pub. No.: US 2016/0108546 A1
(43) Pub. Date: Apr. 21, 2016

(54) LARGE-AREA SINGLE-CRYSTAL MONOLAYER GRAPHENE FILM AND METHOD FOR PRODUCING THE SAME

(71) Applicant: IUCF-HYU (INDUSTRY-UNIVERSITY COOPERATION FOUNDATION HANYANG UNIVERSITY, Seoul (KR)

(72) Inventors: Ho Bum PARK, Seoul (KR); Hansu KIM, Seoul (KR); Hee Wook YOON, Gyeonggi-do (KR); Sun Mi PARK, Gyeonggi-do (KR); Min Yong LEE, Gyeonggi-do (KR)

(21) Appl. No.: 14/892,658

(22) PCT Filed: May 21, 2014
(86) PCT No.: PCT/KR2014/004517

§ 371 Date: Nov. 20, 2015

(30) Foreign Application Priority Data
May 21, 2013 (KR) 10-2013-0057105
May 13, 2014 (KR) 10-2014-0057218

(51) Int. Cl. C30B 1/04; C30B 29/02; H01L 29/45; H01M 4/96; H01L 31/0224; C30B 25/18; C30B 33/00

(52) U.S. Cl. CPC C30B 1/04; C30B 25/18; C30B 29/02; C30B 33/00; H01M 4/96; H01L 31/022466; H01L 29/45

(57) ABSTRACT

The present invention relates to a large-area single-crystal monolayer graphene film in which a graphene layer is formed on a single-crystal metal catalyst layer whose crystal plane orientation is (111) optionally on a substrate. In the large-area single crystal monolayer graphene film of the present invention, a single-crystal metal catalyst layer whose crystal plane orientation is (111) can be formed in the shape of a foil, plate, block or tube optionally on a substrate and a graphene layer is formed on the catalyst layer. The present invention also relates to a method for producing a large-area single-crystal monolayer graphene film whose crystal plane orientation is (111) by annealing and chemical vapor deposition of a metal precursor. According to the method of the present invention, a high-quality large-area graphene thin film applicable as a material for transparent electrodes, display devices, semiconductor devices, separation membranes, fuel cells, solar cells, and sensors can be produced on a commercial scale.

### TECHNICAL FIELD

The present invention relates to a large-area single-crystal monolayer graphene film and a method for producing the same. More specifically, the present invention relates to a large-area single-crystal monolayer graphene film in which a graphene layer is formed on a single-crystal metal catalyst layer whose crystal plane orientation is (111) optionally on a substrate, and a method for producing a large-area single-crystal monolayer graphene film whose crystal plane orientation is (111) by annealing and chemical vapor deposition of a metal precursor.

### BACKGROUND ART

Graphene is a one-atom thick two-dimensional structure of sp²-bonded carbon atoms and has a crystal structure in which hexagonal rings of carbon atoms, similar to benzene rings, are arranged in a honeycomb pattern. Graphene exhibits high visible light transmittance due to its high transparency and have excellent mechanical properties and superior conductivity. Due to these advantages, graphene has received attention as a promising material for transparent electrodes, semiconductor devices, separation membranes, and sensors.

Graphene films are currently produced, for example, by mechanical exfoliation of graphite, chemical exfoliation based on the redox reaction of graphene, epitaxial growth on silicon carbide substrates, and chemical vapor deposition (CVD) on transition metal catalyst layers. Particularly, CVD can be considered a method by which graphene can be produced on a large area at low cost, thus increasing the likelihood of success in the commercialization of graphene films. According to a general CVD method for producing a graphene film, it is known that graphene deposited on a polycrystalline transition metal catalyst layer cannot be grown into a single crystal over large area.

A method for producing a large-area single-crystal graphene film is known in which a single-crystal transition metal catalyst layer is formed on a single-crystal substrate, such as a sapphire or magnesium oxide substrate, by thermal evaporation, e-beam evaporation or sputtering and graphene is deposited on the catalyst layer by CVD (Patent Document 1). However, the formation of the single-crystal transition metal catalyst layer necessitates the use of the expensive single-crystal substrate, which makes the production of the graphene film on a large area economically inefficient. Therefore, the graphene film is difficult to commercialize.

Another method for producing a monolayer graphene film is known which includes forming a transition metal catalyst layer, such as a copper catalyst layer, on a substrate and crystallizing the transition metal catalyst layer by annealing at 800 to 1,000° C. and 1 to 760 torr (Patent Document 2). However, the substrate is essentially required and the transition metal catalyst layer crystallized by annealing is not grown into a high-quality large-area single-crystal monolayer graphene film due to its lack of a single-crystal structure, which makes it difficult to commercialize the graphene film.

Under these circumstances, in an attempt to uniformly deposit graphene on a metal catalyst layer, such as a copper catalyst layer by CVD without the use of an expensive single-crystal substrate, process parameters associated with temperature, pressure, a hydrocarbon gas precursor, and the amount or rate of flow of a gas, such as hydrogen or argon, are controlled to produce a monolayer graphene film. The level of the monolayer structure in the graphene film reaches 95 to 97%, but bilayer, trilayer or multilayer structures coexist and account for about 3 to about 5% of the graphene film. The presence of the multilayer structures prevents the grains from meeting together and migrating in the graphene film to grow into a single crystal of larger grains and instead leads to the formation of a polycrystalline layer in which grain boundaries are oriented in a variety of directions.

In recent years, research has been conducted on the production of a single-crystal monolayer graphene film in which the level of the monolayer structure reaches almost 100%, by CVD without using a an expensive single-crystal substrate (Non-Patent Document 1). According to this research, the process parameters are controlled such that crystal nuclei are grown to the largest possible size on a copper catalyst layer. It was also reported that the edge-to-edge distance between the hexagonal graphene domains and the surface area of the hexagonal graphene domains amount to a maximum of 2.3 mm and a maximum of 4.5 mm², respectively, which are about 20 times larger than those reported before. However, since a copper foil having a size of at most 1 cm×1 cm was used as the copper catalyst layer, the research still remains at laboratory level. The limited area of the copper foil is an obstacle to the commercialization of the single-crystal monolayer graphene film.

Another method for producing monolayer graphene film is know which a graphitization catalyst, such as a commercial copper foil, is preliminarily annealed at 500 to 3,000° C. for 10 minutes to 24 hours, followed by chemical polishing (Patent Document 3). However, a single-crystal structure of the graphitization catalyst is not attained under the preliminary annealing conditions. In the Experimental Examples section of Patent Document 3, a monolayer graphene film was produced on a copper foil having a size of about 1 cm ×1 cm as a graphitization catalyst. The monolayer graphene film had a single-crystal structure as a determinant of high quality but could not be produced over a large area.

Patent Document 1: Korean Patent Publication No. 10-2013-0020351

Patent Document 2: Korean Patent No. 10-1132706

Patent Document 3: Korean Patent Publication No. 10-2013-0014182

Non-Patent Document 1: Zheng Yan et al., ACS Nano 2012, 6 (10), 9110-9117

### DETAILED DESCRIPTION OF THE INVENTION

### Problems to be Solved by the Invention

The present invention has been made in view of the above problems and an object of the present invention is to provide a large-area single-crystal monolayer graphene film in which a graphene layer is formed on a single-crystal metal catalyst layer whose crystal plane orientation is (111) optionally on a substrate, and a method for producing a single-crystal monolayer graphene film whose crystal plane orientation is (111) over a large area by annealing and chemical vapor deposition of a metal catalyst layer.

### Means for Solving the Problems

One aspect of the present invention provides a large-area single-crystal monolayer graphene film including a single-crystal metal catalyst layer whose crystal plane orientation is (111) optionally on a substrate and a graphene layer formed on the single-crystal metal catalyst layer.

The substrate is a single-crystal substrate or a non-single-crystalline substrate.

The substrate is a silicon substrate, a metal oxide substrate or a ceramic substrate.

The substrate is made of a material selected from the group consisting of silicon (Si), silicon dioxide (SiO₂), silicon nitride (Si₃N₄), zinc oxide (ZnO), zirconium dioxide (ZrO₂), nickel oxide (NiO), hafnium oxide (HfO₂), cobalt (II) oxide (CoO), copper (II) oxide (CuO), iron (II) oxide (FeO), magnesium oxide (MgO), α-aluminum oxide (α-Al₂O₃), aluminum oxide (Al₂O₃), strontium titanate (SrTiO₃), lanthanum aluminate (LaAlO₃), titanium dioxide (TiO₂), tantalum dioxide (TaO₂), niobium dioxide (NbO₂), and boron nitride (BN).

The single-crystal metal catalyst layer is composed of a metal selected from the group consisting of copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir), and zirconium (Zr).

The single-crystal metal catalyst layer is in the shape of a foil, plate, block or tube.

A further aspect of the present invention provides a method for producing a large-area single-crystal monolayer graphene film, including i) preparing a polycrystalline metal precursor whose crystal planes are oriented in different directions without bias, ii) subjecting the metal precursor to annealing and in-situ chemical vapor deposition to form a single-crystal metal catalyst layer whose crystal plane orientation is (111), and iii) forming a graphene layer on the single-crystal metal catalyst layer.

The metal precursor prepared in step i) is selected from the group consisting of copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir), and zirconium (Zr).

The metal precursor prepared in step i) is in the shape of a foil, plate, block or tube.

The metal precursor prepared in step i) is a commercial copper foil.

The commercial copper foil has a thickness in the range of 5 μm to 18 μm.

In step ii), the annealing is performed in a hydrogen or hydrogen/argon mixed gas atmosphere at 900 to 1,200° C. and 1 to 760 torr for 1 to 5 hours.

The hydrogen atmosphere is created by feeding hydrogen at a flow rate of 10 to 100 sccm.

and the hydrogen/argon mixed gas atmosphere is created by feeding hydrogen at a flow rate of 10 to 100 sccm and argon at a flow rate of 10 to 100 sccm.

In step ii), the chemical vapor deposition is performed in an atmosphere of a mixed gas of hydrogen and a carbon-containing gas at 900 to 1,200° C. and 0.1 torr to 760 torr for 10 minutes to 3 hours.

The atmosphere of a mixed gas of hydrogen and a carbon-containing gas is created by feeding hydrogen at a flow rate of 1 to 100 sccm and a carbon-containing gas at a flow rate of 10 to 100 sccm.

The carbon-containing gas is selected from the group consisting of hydrocarbon gases, gaseous hydrocarbon compounds, C₁-C₆ gaseous alcohols, carbon monoxide, and mixtures thereof.

The hydrocarbon gas is selected from the group consisting of methane, ethane, propane, butane, ethylene, propylene, butylene, acetylene, butadiene, and mixtures thereof.

The gaseous hydrocarbon compound is selected from the group consisting of pentane, hexane, cyclohexane, benzene, toluene, xylene, and mixtures thereof.

The method further includes artificially cooling the final graphene film after step iii).

The cooling is slowly performed at a rate of 10 to 50° C./min.

The cooling is performed by feeding hydrogen at a flow rate of 10 to 1,000 sccm.

Another aspect of the present invention provides a transparent electrode including the large-area single-crystal monolayer graphene film.

Another aspect of the present invention provides a display device including the large-area single-crystal monolayer graphene film.

Another aspect of the present invention provides a semiconductor device including the large-area single-crystal monolayer graphene film.

Another aspect of the present invention provides a separation membrane including the large-area single-crystal monolayer graphene film.

Another aspect of the present invention provides a fuel cell including the large area single-crystal monolayer graphene film.

Another aspect of the present invention provides a solar cell including the large-area single-crystal monolayer graphene film.

Yet another aspect of the present invention provides a sensor including the large-area single-crystal monolayer graphene film.

### Effects of the Invention

In the large-area single-crystal monolayer graphene film of the present invention, a single-crystal metal catalyst layer whose crystal plane orientation is (111) can be formed in the shape of a foil, plate, block, or tube optionally on a substrate and a graphene layer is formed on the catalyst layer. According to the method of the present invention, a high-quality large-area graphene thin film applicable as a material for transparent electrodes, display devices, semiconductor devices, separation membranes, fuel cells, solar cells, and sensors can be produced on a commercial scale.

### BRIEF DESCRIPTION OF THE DRAWINGS

FIG. 1 shows diagrams and images of (a) a conventional graphene layer, which was formed on a copper (100) single crystal epitaxially grown on a single-crystal (100) sapphire substrate by chemical vapor deposition, and (b) another conventional graphene layer, which was formed on a copper (111) single crystal epitaxially grown on a single-crystal (111) magnesium oxide substrate by chemical vapor deposition.

FIG. 2 is a scanning electron microscopy (SEM) image of a commercial copper foil used in Example 1.

FIG. 3 is an X-ray diffraction (XRD) pattern of a commercial copper foil used in Example 1.

FIG. 4 shows scanning electron microscopy (SEM) images of a graphene layer formed on a commercial copper foil as a catalyst layer in Example 1.

FIG. 5 is an X-ray diffraction (XRD) pattern of a graphene layer formed on a commercial copper foil as a catalyst layer in Example 1.

FIG. 6 is an electron backscatter diffraction (EBSD) pattern of a copper catalyst layer formed in Example 1.

FIG. 7 is a Raman spectrum of a graphene layer formed in Example 1.

FIG. 8 shows Raman maps of a graphene layer formed in Example 1.

FIG. 9 shows scanning electron microscopy (SEM) images of a graphene layer formed on a commercial copper foil as a catalyst layer in Comparative Example 1.

FIG. 10 shows scanning electron microscopy (SEM) images of a graphene layer formed on a commercial copper foil as a catalyst layer in Comparative Example 2.

FIG. 11 is an electron backscatter diffraction (EBSD) pattern of a copper catalyst layer formed in Comparative Example 2.

FIG. 12 is an X-ray diffraction (XRD) pattern of a graphene layer formed on a commercial copper foil as a catalyst layer in Comparative Example 2.

FIG. 13 shows scanning electron microscopy (SEM) images of a graphene layer formed on a commercial copper foil as a catalyst layer in Comparative Example 3.

FIG. 14 is a graph comparing the sheet resistance of a single-crystal monolayer graphene film produced in Example 1 with that of a polycrystalline monolayer graphene film reported in the literature.

FIG. 15 is a graph comparing the carrier mobility of a single-crystal monolayer graphene film produced in Example 1 with that of a polycrystalline monolayer graphene film reported in the literature.

FIG. 16 is a graph comparing the transmittance values of a single-crystal monolayer graphene film produced in Example 1 with those of a polycrystalline monolayer graphene film reported in the literature.

### BEST MODE FOR CARRYING OUT THE INVENTION

The present invention is directed to a large-area single-crystal monolayer graphene film and a method for producing the same. A detailed description will now be given of the present invention with reference to the accompanying drawings.

Generally, a metal catalyst layer formed on an amorphous substrate, such as a silicon oxide (SiO₂) film, has a polycrystalline structure. Graphene may be directly formed on a foil or sheet made of a metal, such as copper, nickel or cobalt, without an underlying substrate by a general chemical vapor deposition method. Also in this case, since the metal foil or sheet per se is polycrystalline, the graphene has domains and domain boundaries. The presence of the domains and domain boundaries deteriorates the quality of the graphene and makes it difficult to form the graphene on a large area.

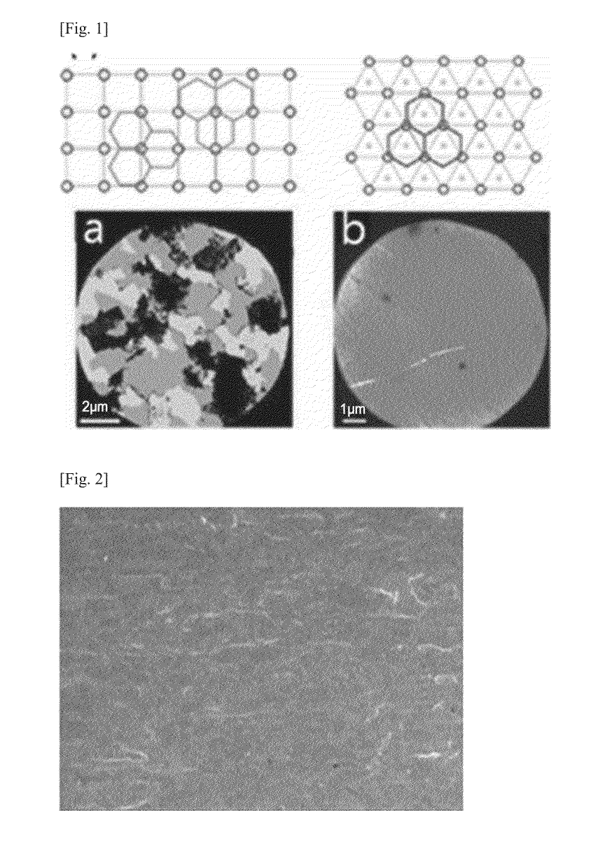

As shown in (a) of FIG. 1, a conventional graphene layer formed on a copper (100) single crystal epitaxially grown on a single-crystal (100) sapphire substrate by a chemical vapor deposition process has two plane directions (0° and 30°). In contrast, a conventional graphene layer formed on a copper (111) single crystal epitaxially grown on a single-crystal (111) magnesium oxide substrate by a chemical vapor deposition process has a single plane free of grain boundaries, as shown in (b) of FIG. 1. The absence of grain boundaries in the graphene layer enables the production of a single crystal monolayer film. However, the epitaxial growth of the copper thin film whose crystal plane is (111) requires the use of an expensive single-crystal (111) magnesium oxide or sapphire substrate.

When the hexagonal graphene layers having the hexagonal (111) plane are bound by chemical reactions on account of the physical properties of graphene to form a layer, the nuclei meet together without defects and migrate no matter which direction they rotate and grow in. As a result, a single-crystal monolayer film free of grain boundaries can be formed.

In view of the foregoing, the present invention is intended to produce a large-area single-crystal monolayer graphene film in which a single-crystal metal foil layer whose crystal plane orientation is (111) is formed by special annealing and in-situ chemical vapor deposition of a polycrystalline metal foil whose crystal planes are oriented in different directions without bias, without using an expensive substrate for the growth of a single crystal having the copper (111) crystal plane, and a graphene layer is formed on the single-crystal metal foil layer, unlike the prior art.

Specifically, the present invention provides a large-area single-crystal monolayer graphene film including a single-crystal metal catalyst layer whose crystal plane orientation is (111) optionally on a substrate and a graphene layer formed on the single-crystal metal catalyst layer.

A feature of the present invention is that the single-crystal metal catalyst layer can be formed even without using an expensive single-crystal substrate, such as a magnesium oxide or sapphire substrate. However, it is to be understood that a single-crystal substrate can be used to form the metal catalyst layer, as in the prior art. Alternatively, a non-single-crystalline substrate may be used.

The single-crystal or non-single-crystalline substrate may be a silicon substrate, a metal oxide substrate or a ceramic substrate. Examples of suitable materials for the substrate include, but are not limited to, silicon (Si), silicon dioxide (SiO₂), silicon nitride (Si₃N₄), zinc oxide (ZnO), zirconium dioxide (ZrO₂), nickel oxide (NiO), hafnium oxide (HfO₂), cobalt (II) oxide (CoO), copper (II) oxide (CuO), iron (II) oxide (FeO), magnesium oxide (MgO), α-aluminum oxide (α-Al₂O₃), aluminum oxide (Al₂O), strontium titanate (SrTiO₃), lanthanum aluminate (LaAl₂O₃), titanium dioxide (TiO₂), tantalum dioxide (TaO₂), niobium dioxide (NbO₂), and boron nitride (BN).

Examples of suitable materials for the single-crystal metal catalyst layer whose crystal plane orientation is (111) include, but are not limited to, copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir), and zirconium (Zr). The single-crystal metal catalyst layer is more preferably composed of copper (Cu).

The shape of the single-crystal metal catalyst layer whose crystal plane orientation is (111) may be a foil, plate, block or tube but is not limited thereto. The single crystal metal catalyst layer is preferably in the shape of a foil.

The large-area single-crystal monolayer graphene film of the present invention in which the graphene layer is formed on the single-crystal metal catalyst layer whose crystal plane orientation is (111) can be produced by the following method.

Specifically, the present invention provides a method for producing a large-area single-crystal monolayer graphene film, including i) preparing a polycrystalline metal precursor whose crystal planes are oriented in different directions without bias, ii) subjecting the metal precursor to annealing and in-situ chemical vapor deposition to form a single-crystal metal catalyst layer whose crystal plane orientation is (111), and iii) forming a graphene layer on the single-crystal metal catalyst layer.

According to a conventional method for producing a graphene film by a chemical vapor deposition process, graphene is deposited on a polycrystalline transition metal catalyst layer. However, the conventional method suffers from a limitation in that graphene cannot be grown into a single crystal over a large area. The present invention is intended to overcome this limitation. First, a polycrystalline metal precursor whose crystal planes are oriented in different directions without bias is prepared as a precursor for the formation of a single-crystal metal catalyst layer, as in the prior art.

As the polycrystalline metal precursor whose crystal planes are oriented in different directions, there may be used a metal selected from the group consisting of copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir), and zirconium (Zr). The metal precursor may take the form of a foil, plate, block or tube but is preferably in the form of a foil, which is advantageous in forming a uniform singe-crystal metal catalyst layer by annealing. Particularly, a commercial copper foil is more preferably used due to its ease of purchase and low price.

Importantly, the polycrystalline metal precursor undergoing annealing in step ii) is required to have crystal planes oriented in different directions without bias. If the polycrystalline metal precursor is dominantly oriented in the (100) crystal plane or is predominantly oriented in the directions of crystal planes other than the crystal plane, the crystal plane directions of the metal precursor are not altered or the metal precursor cannot have a single-crystal structure whose crystal plane orientation is (111) even by annealing.

In addition to the crystallinity and crystal plane orientation of the metal precursor, the thickness of the metal precursor is considered another important factor for the formation of a single-crystal metal catalyst layer whose crystal plane orientation is (111). Particularly, the metal precursor in the form of a foil affects the solid solubility of carbon depending on its thickness in the course of recrystallization after annealing and the formation of a graphene layer by chemical vapor deposition. Thus, the thickness of the metal precursor is preferably adjusted to the range of 5 μm to 8 μm if the metal precursor is thinner than 5 μm, annealing and chemical vapor deposition are difficult to perform efficiently, and as a result, recrystallization of the metal precursor cannot be expected. Meanwhile, if the metal precursor is thicker than 18 μm, a single-crystal metal catalyst layer whose crystal plane orientation is (111) cannot be obtained despite annealing under the same conditions and instead a metal catalyst layer whose crystal planes are oriented in different directions, like the metal precursor, is obtained or a metal catalyst layer having a crystal structure whose dominant crystal plane is (100) is obtained. Further, a graphene layer formed after subsequent annealing and in-situ chemical vapor deposition has defects, such as grain boundaries, and as a result, a desired monolayer film is not obtained.

Next, in step ii), the polycrystalline metal precursor whose crystal planes are oriented in different directions without bias is crystallized by annealing and in-situ chemical vapor deposition to form a single-crystal metal catalyst layer whose crystal plane orientation is (111).

In step ii), the annealing is performed in a hydrogen or hydrogen/argon mixed gas atmosphere at 900 to 1,200° C. and 1 to 760 torr for 1 to 5 hours to prevent oxidation of the catalyst layer. Preferably, the hydrogen atmosphere is created by feeding hydrogen at a rate of 10 to 100 sccm and the hydrogen/argon mixed gas atmosphere is created by feeding hydrogen at a rate of 10 to 100 sccm and argon at a rate of 10 to 100 sccm. The annealing temperature, pressure, and time and the flow rate of hydrogen or hydrogen/argon mixed gas become parameters for the annealing process. Particularly, the annealing pressure is very important. If the parameters are outside the respective ranges defined above, the desired single-crystal metal catalyst layer whose crystal plane orientations is (111) is not formed and it is thus difficult to form a high-quality graphene thin film in the subsequent step. By adjusting the process parameters for the annealing in step ii) within the respective ranges defined above, the metal precursor can be crystallized to form the desired single-crystal metal catalyst layer whose crystal plane orientation is (111), and subsequently, a high-quality single-crystal monolayer graphene layer can be formed in subsequent step iii).

In conclusion, the present invention is fundamentally distinguished in terms of its technical spirit from the prior art in which a single-crystal metal thin film is formed on a single-crystal substrate or a polycrystalline metal catalyst layer is formed by annealing a metal precursor without the use of a substrate. According to the prior art, a graphene layer is formed on a copper foil precursor having a size of at most 1 cm×1 cm. In contrast, according to the present invention, after a metal precursor is subjected to annealing and chemical vapor deposition irrespective of its size, a single-crystal monolayer graphene film can be produced over a large area corresponding to the size of the metal precursor. Therefore, the present invention enables the production of the single-crystal monolayer graphene film on a commercial scale.

In step ii), the chemical vapor deposition is performed in an atmosphere of a mixed gas of hydrogen and a carbon-containing gas at 900 to 1,200° C. and 0.1 torr to 760 torr for 10 minutes to 3 hours. The atmosphere of a mixed gas of hydrogen and a carbon-containing gas is created by feeding hydrogen at a flow rate of 1 to 100 sccm and a carbon containing gas at a flow rate of 10 to 100 sccm. The carbon-containing gas is selected from the group consisting of hydrocarbon gases, gaseous hydrocarbon compounds, C₁-C₆ gaseous alcohols, carbon monoxide, and mixtures thereof. A hydrocarbon gas is particularly preferably used.

Examples of the hydrocarbon gases include methane, ethane, propane, butane, ethylene, propylene, butylene, acetylene, and butadiene. These hydrocarbon gases may to be used alone or as a mixture thereof. Methane is more preferred for its ease of handling. Examples of the gaseous hydrocarbon compounds include, but are not limited to, pentane, hexane, cyclohexane, benzene, toluene, and xylene. These gaseous hydrocarbon compounds may be used alone or as a mixture thereof.

After step ii), a desired large-area single-crystal monolayer graphene film can be obtained in step iii). The method may optionally further include artificially cooling the final graphene film after step iii). Preferably, the cooling is slowly performed at a rate 10 to 50° C./min. If the graphene film is rapidly cooled at a rate exceeding the upper limit defined above, defects may be formed in the graphene during uniform growth and arrangement of the graphene. Accordingly, special care must be taken to avoid the formation of defects in the graphene. An oxidizing atmosphere may be created in the cooling step. The oxidizing atmosphere may be avoided by feeding hydrogen at a rate of 10 to 1,000 sccm.

The present invention also provides a transparent electrode, a display device, a semiconductor device, a separation membrane, a fuel cell, a solar cell, and a sensor, each of which includes the large-area single-crystal monolayer graphene film.

Hereinafter, specific embodiments of the present invention will be explained in detail.

### MODE FOR CARRYING OUT THE INVENTION

### EXAMPLE 1

An 18 μm thick, 10 cm wide, and 10 cm long copper foil (HOHSEN, 99.9%, Japan) as a metal precursor was introduced into a chamber. The copper foil was annealed while feeding 100 sccm of hydrogen into the chamber at 1,005° C. and 500 torr for 2 h. As a result of the annealing, a copper catalyst layer was formed. Simultaneously, chemical vapor deposition (CVD) was performed while feeding a mixed gas of hydrogen (5 sccm)/methane (20 sccm) into the chamber at 1,005° C. and 0.5 torr for 60 min. As a result, a graphene layer was formed on the copper catalyst layer.

### EXAMPLES 2-3 AND COMPARATIVE EXAMPLES 1-3

Graphene films were produced in the same manner as in Example 1, except that the annealing and CVD process parameters were changed as shown in Table 1.

TABLE 1

| | | | | Atmosphere | | | | Atmosphere | |
|---|---|---|---|---|---|---|---|---|---|
| | Thickness | Temperature¹⁾ | Pressure¹⁾ | (hydrogen)¹⁾ | | Temperature²⁾ | Pressure²⁾ | (hydrogen/methane)²⁾ | |
| Example No. | (μm) | (° C.) | (torr) | Time | | (° C.) | (torr) | Time | |
| Example 1 | 18 | 1,005 | 500 | 100 | sccm | 1,005 | 0.5 | 5/20 | sccm |
| | | | | 2 | h | | | 60 | min |
| Example 2 | 18 | 1,005 | 500 | 50 | sccm | 1,005 | 0.5 | 5/20 | sccm |
| | | | | 2 | h | | | 60 | min |
| Example 3 | 18 | 1,005 | 500 | 100 | sccm | 1,020 | 500 | 5/20 | sccm |
| | | | | 2 | h | | | 30 | min |
| Comparative | 18 | None | None | None | | 1,005 | 0.5 | 5/20 | sccm |
| Example 1 | | | | | | | | 60 | min |
| Comparative | 18 | 1,005 | 0.5 | 20 | sccm | 1,005 | 0.5 | 5/20 | sccm |
| Example 2 | | | | 2 | h | | | 60 | min |
| Comparative | 75 | 1,005 | 500 | 100 | sccm | 1,005 | 0.5 | 5/20 | sccm |
| Example 3 | | | | 2 | h | | | 60 | min |

*Each copper foil had a size of 10 cm (w) × 10 cm (l)
¹⁾Annealing
²⁾CVD

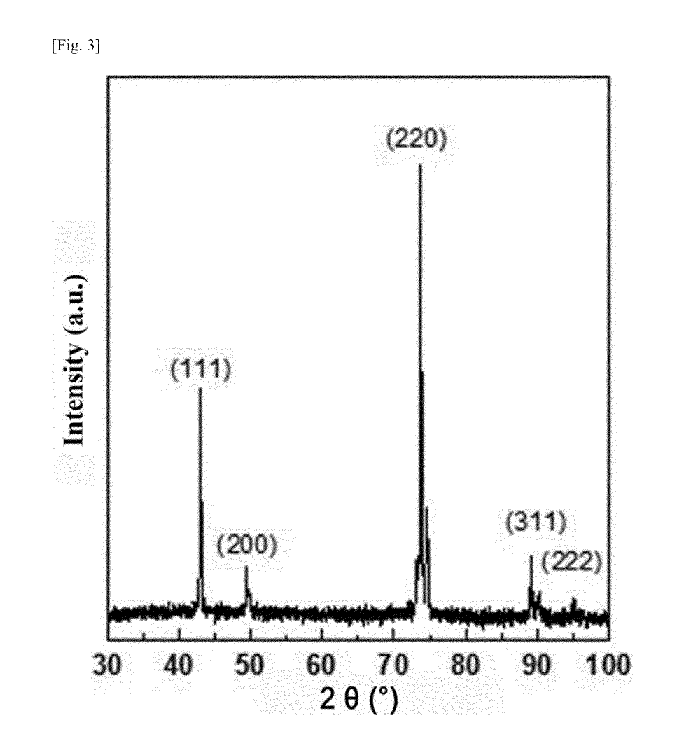

FIG. 2 is a scanning electron microscopy (SEM) image of the commercial copper foil used as a metal precursor in Example 1. The image reveals the presence of grains and grain boundaries in the copper foil. FIG. 3 is an X-ray diffraction (XRD) pattern of the commercial copper foil measured to determine the crystallinity of the copper foil. The XRD pattern confirms that the copper foil had various crystal plane orientations (polycrystallinity).

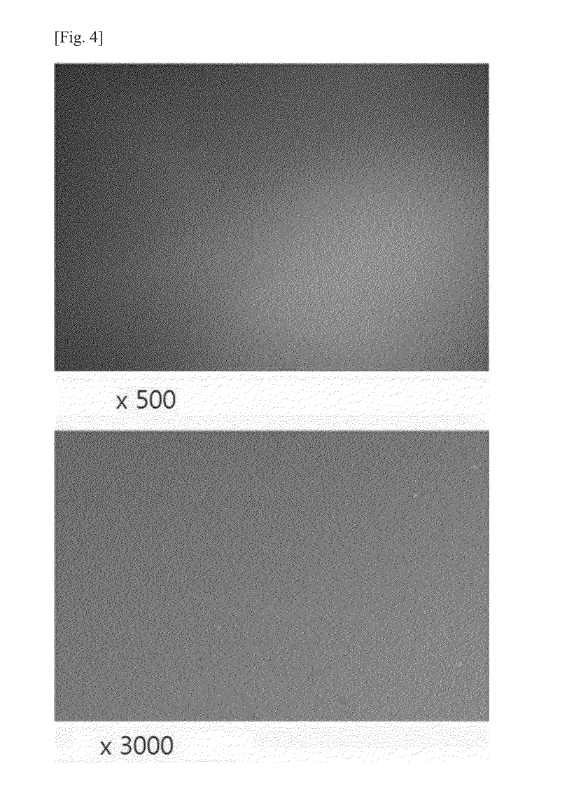

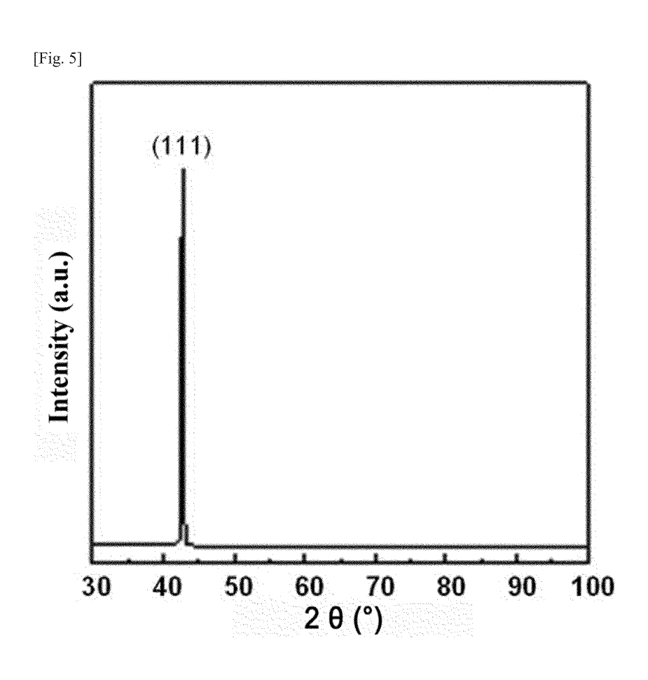

FIG. 4 shows scanning electron microscopy (SEM) images of the graphene layer formed on the commercial copper foil after annealing and chemical vapor deposition (CVD) in Example 1. As can be seen from the SEM images, grain boundaries disappeared in the copper catalyst layer. FIG. 5 is an X-ray diffraction (XRD) pattern of the graphene layer formed on the commercial copper foil. The XRD pattern confirms the formation of the single-crystal catalyst layer whose crystal plane orientation is (111) after recrystallization by annealing and chemical vapor deposition.

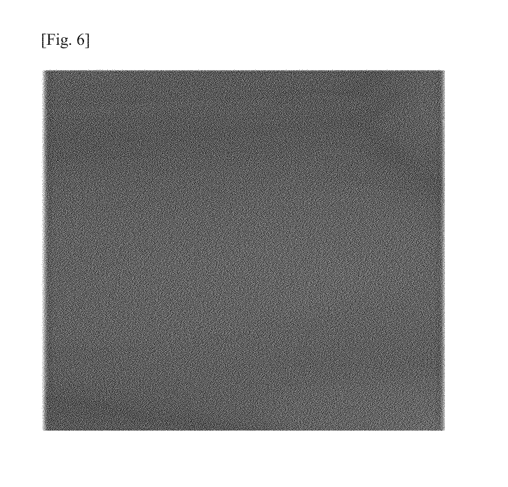

An electron backscatter diffraction (EBSD) pattern of the copper catalyst layer formed in Example 1 was measured to further analyze the crystal plane orientation of the copper catalyst layer and is shown in FIG. 6. The EBSD pattern confirms the formation of the single-crystal copper catalyst layer free of grain boundaries and defects over the entire area and whose crystal plane orientation is (111).

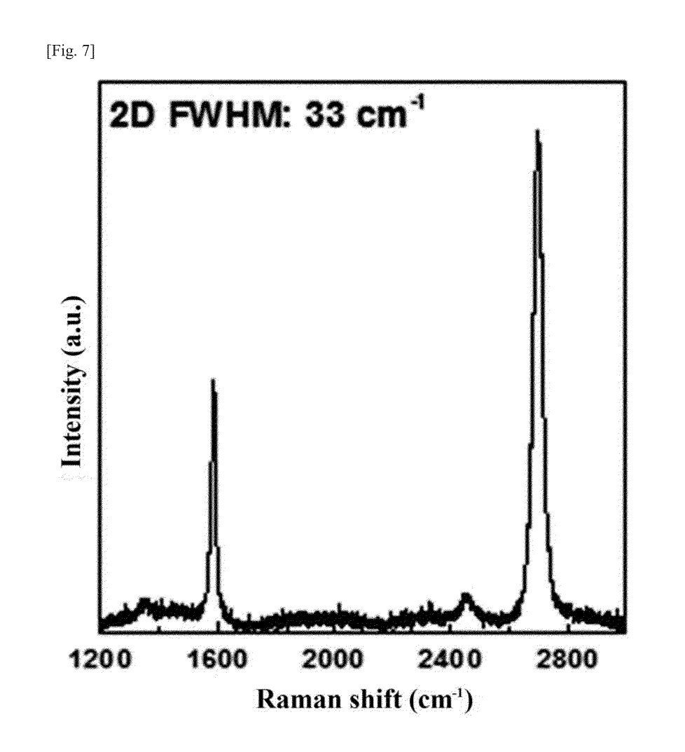

FIG. 7 is a Raman spectrum of the graphene layer formed in Example 1. G peak characteristic to graphene was observed at around 1580 cm⁻¹. Particularly, strong and sharp 2D peak was observed at around 2700 cm⁻¹, indicating that the graphene layer was in the form of a monolayer. The intensity of D peak at around 1.340 cm⁻¹, which is commonly observed in graphene, was too weak in intensity to measure. These observations demonstrate that the graphene layer formed in Example 1 was almost free of defects. The relative ratio of the intensity of D peak to the Intensity of G peak was measured to be about 0.22, demonstrating very high crystallinity of the graphene layer.

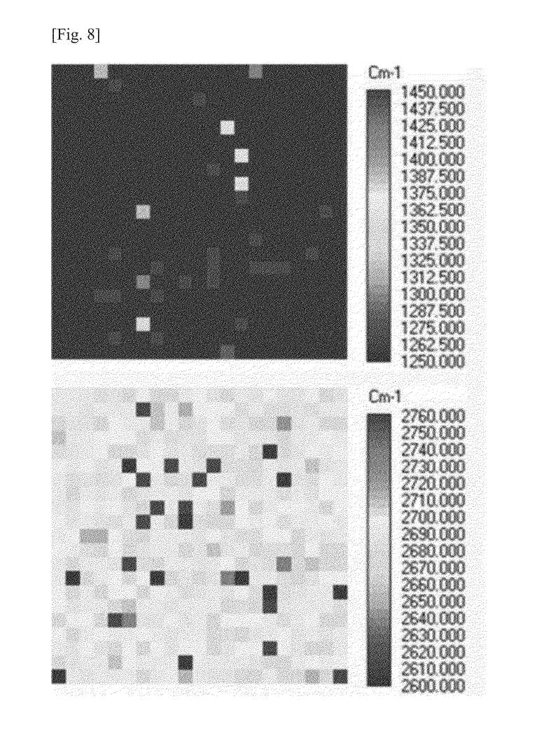

FIG. 8 shows Raman maps of the graphene layer formed in Example 1. Upon D1 mapping, defects, such as wrinkles, cracks, and grain boundaries, were not observed in the graphene layer. Upon D2 mapping, D2 peaks only were measured over the entire area of the graphene layer, indicating that the graphene layer was in the form of a monolayer. The production of a large-area single-crystal monolayer graphene film was also confirmed by the Raman mapping.

Although not shown, the same results of Example 1 were also obtained in Example 2 in which the flow rate of hydrogen as a source for the annealing atmosphere was changed and Example 3 in which the CVD process conditions were changed.

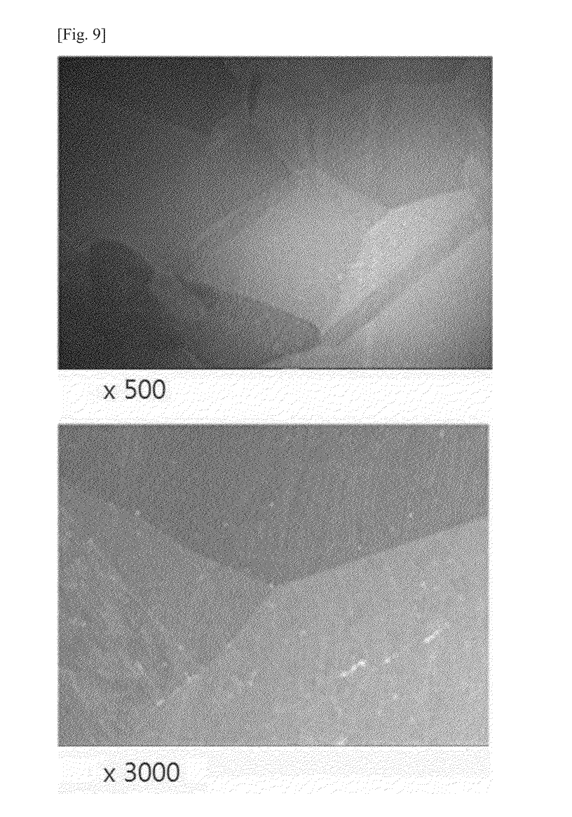

FIG. 9 shows scanning electron microscopy (SEM) images of the graphene layer formed on the commercial copper foil in Comparative Example 1. As shown in FIG. 9, when chemical vapor deposition was performed under the same conditions as in Example 1 without annealing of the copper foil, grains and grain boundaries remained in the graphene, indicating that a high quality single-crystal monolayer graphene film cannot be obtained.

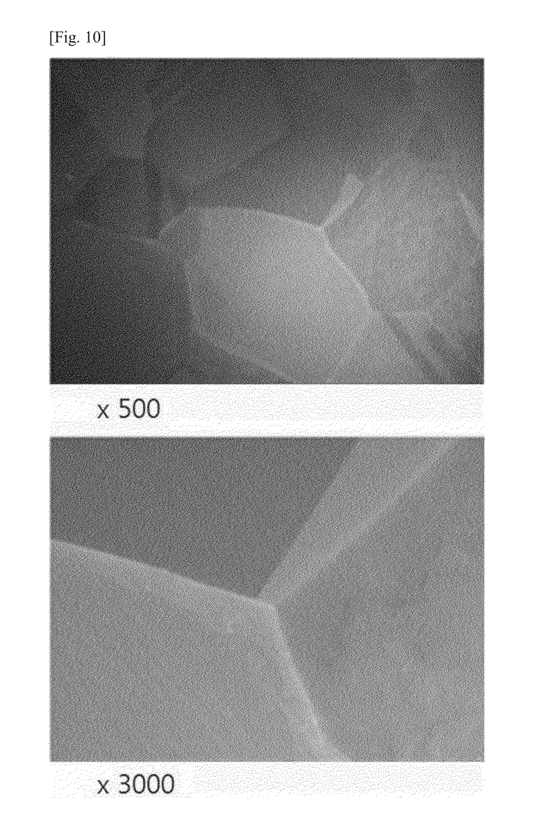

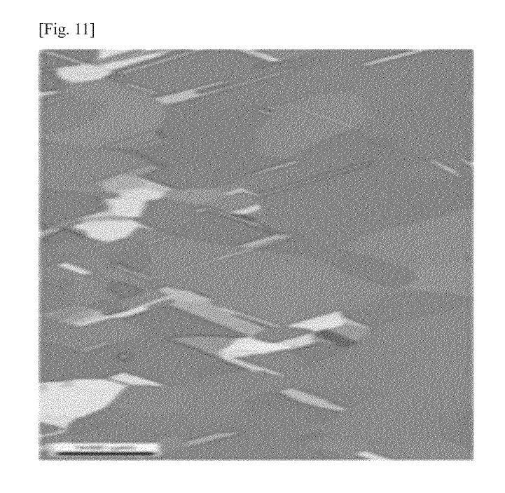

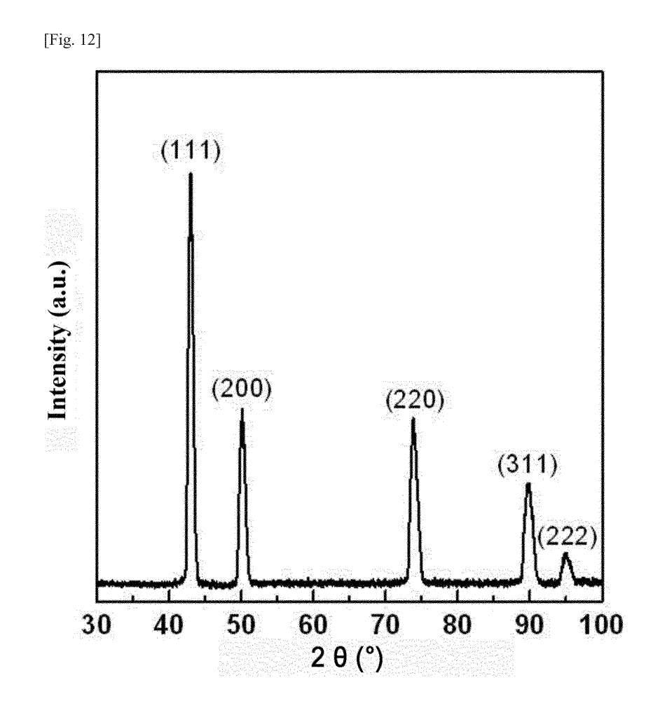

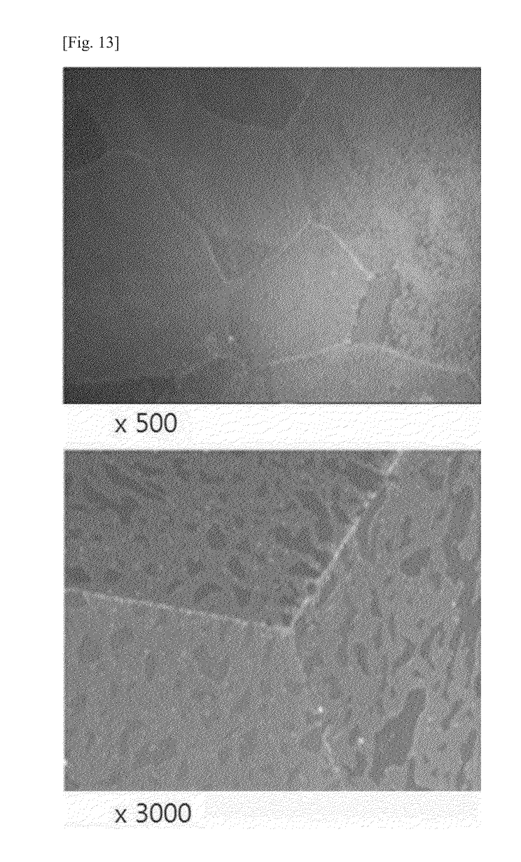

FIGS. 10 and 11 show scanning electron microscopy (SEM) images of the graphene layer formed in Comparative Example 2 and an electron backscatter diffraction (EBSD) pattern of the copper catalyst layer formed in Comparative Example 2, respectively. As shown in these figures, copper grains and grain boundaries still remained in the copper catalyst layer when CVD was performed under the same conditions as in Example 1 but the commercial copper foil was annealed at a relatively low pressure. FIG. 12 is an X-ray diffraction (XRD) pattern of the graphene layer formed on the commercial copper foil in Comparative Example 2. The XRD pattern reveals that the polycrystallinity of the copper foil as a metal precursor remained unchanged even after annealing and CVD processes.

FIG. 13 shows scanning electron microscopy (SEM) images of the graphene layer formed on the 75 μm commercial copper foil in Comparative Example 3. As shown in FIG. 13, copper grains and grain boundaries still remained in the copper catalyst layer when the thick copper foil as a metal precursor was subjected to annealing and CVD under the same conditions as in Examples 1-3. Although not shown in Table 1, copper foils with different thicknesses were subjected to annealing and CVD. As a result, when a copper foil thicker than 18 μm was used, a single-crystal monolayer graphene film was not obtained. Meanwhile, when a copper foil thinner than 5 was used, annealing and CVD were impossible to perform efficiently.

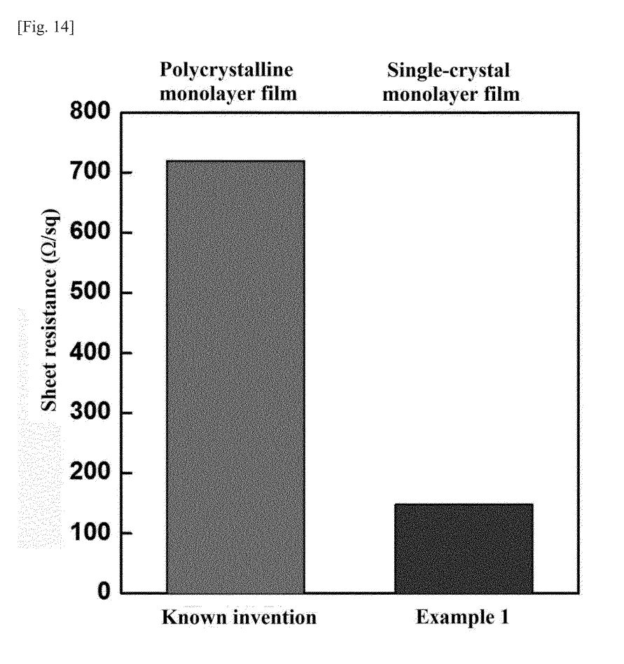

The sheet resistance, carrier mobility, and transmittance values of the single-crystal monolayer film produced in Example 1 were measured to confirm the electrical and optical properties of the single-crystal monolayer graphene film. The results were compared with those of polycrystalline monolayer graphene films reported in the literature and are shown in FIGS. 14 to 16. The single-crystal monolayer film produced in Example 1 was evaluated to have improved electrical and optical properties compared to the conventional polycrystalline monolayer graphene films.

FIG. 14 is a graph comparing the sheet resistance of the single-crystal monolayer graphene film produced in Example 1 with that of a polycrystalline monolayer graphene film reported in the literature [ACS NANO, VOL. 5, 6916 (2011)]. The sheet resistance values were measured using a 4-point probe in accordance with the general method of ASTM D257. As shown in FIG. 14, the sheet resistance of the single crystal monolayer graphene film produced in Example 1 was much lower by about 80% than that of the conventional polycrystalline, monolayer graphene film. This is thought to be because the reduced density of defects, such as grain boundaries, in the single crystal monolayer film led to a decrease in electron mean free path. The single-crystal monolayer graphene film produced in Example 1 is expected to be applicable to a variety of devices, including flexible OLED and solar cell devices as low-power, high-efficiency display devices, beyond touch screens.

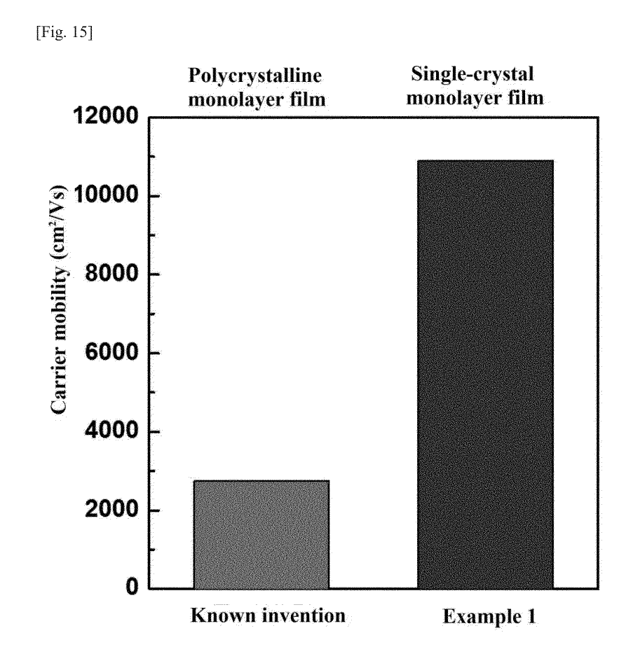

FIG. 15 is a graph comparing the carrier mobility of the single-crystal monolayer graphene film produced in Example 1 with that of a polycrystalline monolayer graphene film reported in the literature [Appl. Phys. Lett., 102, 163102 (2013)]. The carrier mobility values were measured using a hall effect measurement system. The carrier mobility value of the single-crystal monolayer graphene film produced in Example 1 was much higher by about 300% than that of the conventional polycrystalline monolayer graphene film. This is thought to be because the reduced density of defects, such as grain boundaries, in the single-crystal monolayer film led to a decrease in the scattering rate of charge carriers. Therefore, the single-crystal monolayer graphene film produced in Example 1 will be applicable to low-power, high-speed next-generation semiconductor logic devices and next-generation nanoscale (≦10 nm) channel materials.

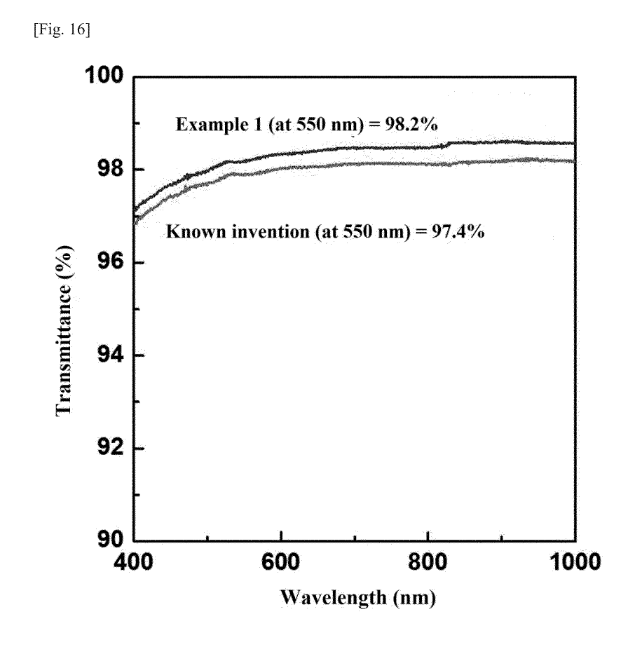

FIG. 16 is a graph comparing the transmittance values of the single-crystal monolayer graphene film produced in Example 1 with those of a polycrystalline monolayer graphene film reported in the literature [Nature Nanotechnology, Vol 5, August (2010)]. As shown in FIG. 16, the transmittance values of the single-crystal monolayer graphene film produced in Example 1 were higher by about 0.8% than those of the conventional polycrystalline monolayer graphene film and are the highest values reported so far. This is thought to be because the reduced density of defects, such as grain boundaries, in the single-crystal monolayer film led to a decrease in the scattering and refraction of transmitted light. Generally, transmittance increases with decreasing thickness and resistance increases with increasing thickness. That is, transmittance and resistance are in a trade-off relationship with respect to thickness. However, the single-crystal monolayer graphene film produced in Example 1 was found to produce synergistic effects on improvement of resistance and transmittance, as described above.

In conclusion, the single-crystal monolayer graphene film of Example 1, which was produced through annealing and chemical vapor deposition of the metal precursor without the use of an expensive substrate, was free of grains and grain boundaries and had high quality compared to the monolayer graphene films of Comparative Examples 1-3 and the monolayer graphene films produced by conventional methods. Particularly, annealing and chemical vapor deposition of the metal precursor in its original state irrespective of its size and shape were surprisingly effective in producing the single-crystal monolayer graphene film over a large area corresponding to the original area of the metal precursor.

### INDUSTRIAL APPLICABILITY

The large-area single-crystal monolayer graphene film of the present invention is expected to be applicable to transparent electrodes, display devices, semiconductor devices, separation membranes, fuel cells, solar cells, and sensors.

1. A large-area single-crystal monolayer graphene film, comprising: a single-crystal metal catalyst layer whose crystal plane orientation is (111) optionally on a substrate; and a graphene layer formed on the single-crystal metal catalyst layer.

2. The large-area single-crystal monolayer graphene film according to claim 1, wherein the substrate is a single-crystal substrate or a non-single-crystalline substrate.

3. The large-area single-crystal monolayer graphene film according to claim 1, wherein the substrate is a silicon substrate, a metal oxide substrate or a ceramic substrate.

4. The large-area single-crystal monolayer graphene film according to claim 3, wherein the substrate is made of a material selected from the group consisting of silicon (Si), silicon dioxide (SiO₂) silicon nitride (Si₃N₄), zinc oxide (ZnO), zirconium dioxide (ZrO₂), nickel oxide (NiO), hafnium oxide (HfO₂), cobalt (II) oxide (CoO), copper (II) oxide (CuO), iron (II) oxide, (FeO), magnesium oxide (MgO), α-aluminum oxide (α-Al₂O₃), aluminum oxide (Al₂O₃), strontium titanate (SrTiO₃), lanthanum aluminate (LaAlO₃), titanium dioxide (TiO₂), tantalum dioxide (TaO₂), niobium dioxide (NbO₂), and boron nitride (BN).

5. The large-area single-crystal monolayer graphene film according to claim 1, wherein the single-crystal metal catalyst layer is composed of a metal selected, from the group consisting of copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir), and zirconium (Zr).

6. The large-area single-crystal monolayer graphene film according to claim 1, wherein the single-crystal metal catalyst layer is in the shape of a foil, plate, block or tube.

7. A method for producing a large-area single-crystal monolayer graphene film, comprising: i) preparing a polycrystalline metal precursor whose crystal planes are oriented in different directions without bias; ii) subjecting the metal precursor to annealing and in-situ chemical vapor deposition to form a single-crystal metal catalyst layer whose crystal plane orientation is (111); and iii) forming a graphene layer on the single-crystal metal catalyst layer.

8. The method according to claim 7, wherein the metal precursor prepared in step i) is selected from the group consisting of copper (Cu), nickel (Ni), cobalt (Co), iron (Fe), ruthenium (Ru), platinum (Pt), palladium (Pd), gold (Au), silver (Ag), aluminum (Al), chromium (Cr), magnesium (Mg), manganese (Mn), molybdenum (Mo), rhodium (Rh), silicon (Si), tantalum (Ta), titanium (Ti), tungsten (W), uranium (U), vanadium (V), iridium (Ir), and zirconium (Zr).

9. The method according to claim 7, wherein the metal precursor prepared in step i) is in the shape of a foil, plate, block or tube.

10. The method according to claim 7, wherein the metal precursor prepared in step i) is a commercial copper foil.

11. The method according to claim 10, wherein the commercial copper foil has a thickness in the range of 5 μm to 18 μm.

12. The method according to claim 7, wherein, in step ii), the annealing is performed in a hydrogen or hydrogen/argon mixed was atmosphere at 900 to 1,200° C. and 1 to 760 torr for 1 to 5 hours.

13. The method according to claim 12, wherein the hydrogen atmosphere is created by feeding hydrogen at a flow rate of 10 to 100 sccm and the hydrogen/argon mixed gas atmosphere is created by feeding hydrogen at a flow rate of 10 to 100 sccm and argon at a flow rate of 10 to 100 sccm.

14. The method according to claim 7, wherein, in step ii), the chemical vapor deposition is performed in an atmosphere of a mixed gas of hydrogen and a carbon-containing gas at 900 to 1,200° C. and 0.1 torr to 760 torr for 10 minutes to 3 hours.

15. The method according to claim 14, wherein the atmosphere of a mixed gas of hydrogen and a carbon-containing gas is created by feeding hydrogen at a flow rate of 1 to 100 sccm and a carbon-containing gas at a flow rate of 10 to 100 sccm.

16. The method according to claim 14, wherein the carbon-containing gas is selected from the group consisting of hydrocarbon gases, gaseous hydrocarbon compounds, C₁-C₆ gaseous alcohols, carbon monoxide, and mixtures thereof.

17. The method according to claim 16, wherein the hydrocarbon gas is selected from the group consisting of methane, ethane, propane, butane, ethylene, propylene, butylene, acetylene, butadiene, and mixtures thereof.

18. The method according to claim 16, wherein the gaseous hydrocarbon compound is selected from the group consisting of pentane, hexane, cyclohexane, benzene, toluene, xylene, and mixtures thereof.

19. The method according to claim 7, further comprising artificially cooling the anal graphene film after step iii).

20. The method according to claim 19, wherein the cooling is slowly performed at a rate of 10 to 50° C./min.

21. The method according to claim 19, wherein the cooling is performed by feeding hydrogen at a flow rate of 10 to 1,000 sccm.

22. A transparent electrode comprising the large-area single-crystal monolayer graphene film according to claim 1.

23. A display device comprising the large-area single-crystal monolayer graphene film according to claim 1.

24. A semiconductor device comprising the large-area single-crystal monolayer graphene film according to claim 1.

25. A separation membrane comprising the large-area single-crystal monolayer graphene film according to claim 1.

26. A fuel cell comprising the large-area single-crystal monolayer graphene film according to claim 1.

27. A solar cell comprising the large-area single-crystal monolayer graphene film according to claim 1.

28. A sensor comprising the large-area single-crystal monolayer graphene film according to claim 1.
